(19) United States
(12) Patent Application Publication
(10) Pub. No.: US 2024/0395990 A1
(43) Pub. Date: Nov. 28, 2024

(54) LIGHT-EMITTING DEVICE

(71) Applicant: STANLEY ELECTRIC CO., LTD., Tokyo (JP)

(72) Inventors: Daizo KAMBARA, Tokyo (JP); Yoichi SHIMODA, Tokyo (JP); Maiko TANABE, Tokyo (JP)

(73) Assignee: STANLEY ELECTRIC CO., LTD., Tokyo (JP)

(21) Appl. No.: 18/665,182

(22) Filed: May 15, 2024

(30) Foreign Application Priority Data
May 22, 2023 (JP) 2023-083846

(51) Int. Cl. H01L 33/60; H01L 33/02; H01L 33/50

(52) U.S. Cl. CPC H01L 33/60; H01L 33/025; H01L 33/502

(57) ABSTRACT

To provide a light-emitting device that is able to reduce a light loss and achieve a narrow angled emitted light. The light-emitting device comprises: a light-emitting element having a rectangular parallelepiped shape and having an element electrode surface on which a pair of element electrodes made of a cathode and an anode are formed on a lower surface and a light-emitting surface on an upper surface opposed to the element electrode surface; a translucent light-collecting member disposed on the light-emitting surface of the light-emitting element and having a plurality of light emission regions separated away from one another on a surface opposite of a surface opposed to the light-emitting surface; and an optical structure formed to respectively overlap a plurality of the respective light emission regions viewed from above and having a plurality of convex lens portions in convex in an upper side.

### BACKGROUND

### 1. Technical Field

The present invention relates to a light-emitting device including a light-emitting element.

### 2. Description of the Related Art

Conventionally, there has been known a light-emitting device that uses a light-emitting element, such as a light-emitting diode (LED), as a light source.

For example, WO 2005/029597 discloses a light-emitting device including a light-emitting element mounted on a substrate, a resin layer that covers the substrate and the light-emitting element and has a lens portion formed in a light-emitting element region, and a reflective plate that surrounds an outer periphery of the lens portion on the resin layer.

For example, when a light-emitting device that uses an LED as a light source is used for a light source of a display device, such as a head-up display (HUD), the HUD includes an optical system that deflects a light emitted from the light-emitting device. In this case, the light emitted from the light-emitting device is preferably emitted in a narrow angle range in order to downsize the optical system that is located downstream from thereof.

However, when the conventional light-emitting device is used as a light source, it is possible that the light emitted from the light-emitting element enters the resin layer covering the substrate as a stray light resulting in increasing a light loss.

### SUMMARY OF THE INVENTION

The present invention has been made in consideration of the problem described above, and an objective is to provide a light-emitting device that is able to reduce a light loss and achieve a narrow angled emitted light.

A light-emitting device according to the present invention includes a light-emitting element, a translucent light-collecting member, and an optical structure. The light-emitting element has a rectangular parallelepiped shape. The light-emitting element has an element electrode surface on which a pair of element electrodes made of a cathode and an anode are formed on a lower surface and a light-emitting surface on an upper surface opposed to the element electrode surface. The translucent light-collecting member is disposed on the light-emitting surface of the light-emitting element, the light-collecting member having a plurality of light emission regions separated away from one another on a surface opposite of a surface opposed to the light-emitting surface. The optical structure is formed to respectively overlap a plurality of the respective light emission regions viewed from above, the optical structure having a plurality of convex lens portions in convex in an upper side.

Other objectives and advantages of this invention will become apparent from the following description taken in conjunction with the accompanying drawings wherein are set forth, by way of illustration and example, certain embodiments of this invention. The drawings constitute a part of this specification and include exemplary embodiments of the present invention and illustrate various objects and features thereof.

### BRIEF DESCRIPTION OF THE DRAWINGS

FIG. 1 is a top view of a light-emitting device according to an example of the present invention;

FIG. 2 is a cross-sectional view of the light-emitting device according to the example of the present invention;

FIG. 3 is a top view of a light-collecting member of the light-emitting device according to the example of the present invention;

FIG. 4 is an enlarged cross-sectional view of the light-collecting member and an optical structure of the light-emitting device according to the example of the present invention;

FIG. 5 is a cross-sectional view of a light-emitting device according to a comparative example of the present invention;

FIG. 6 is a drawing illustrating a light distribution property of an emitted light of the light-emitting device according to the comparative example of the present invention;

FIG. 7 is a drawing illustrating a light distribution property of an emitted light of the light-emitting device according to the example of the present invention;

FIG. 8 is an enlarged cross-sectional view of a light-collecting member and an optical structure according to Modification 1 of the present invention;

FIG. 9 is a cross-sectional view of a light-emitting device according to Modification 2 of the present invention; and

FIG. 10 is a cross-sectional view of a light-emitting device according to Modification 3 of the present invention.

### DETAILED DESCRIPTION

The following describes details of examples of the present invention. Note that substantially the same or equivalent portions have the same reference numerals in the following description and the attached drawings.

### Example 1

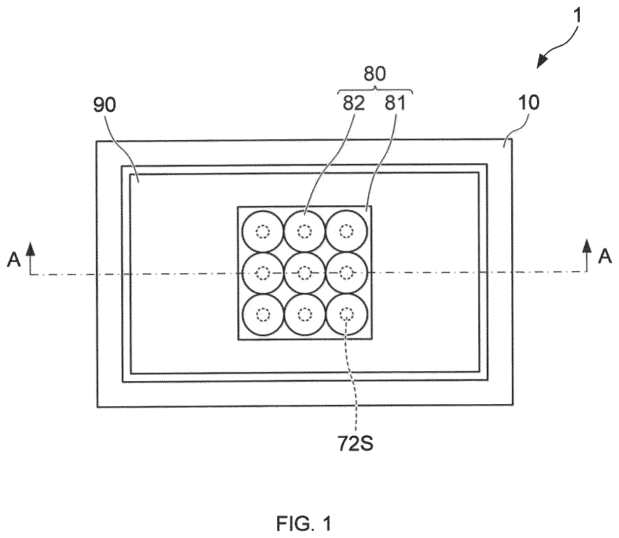

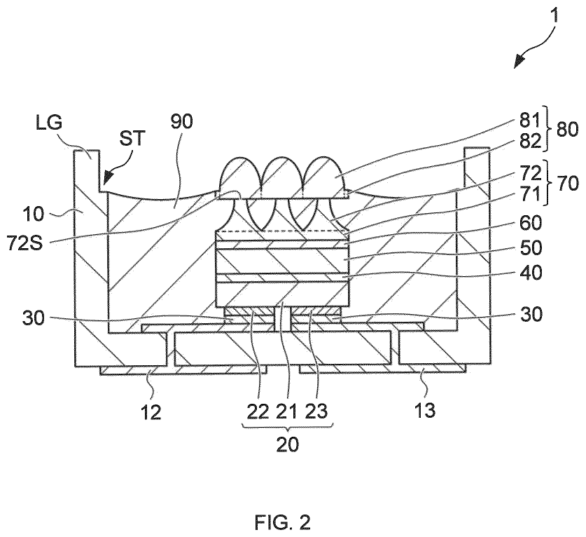

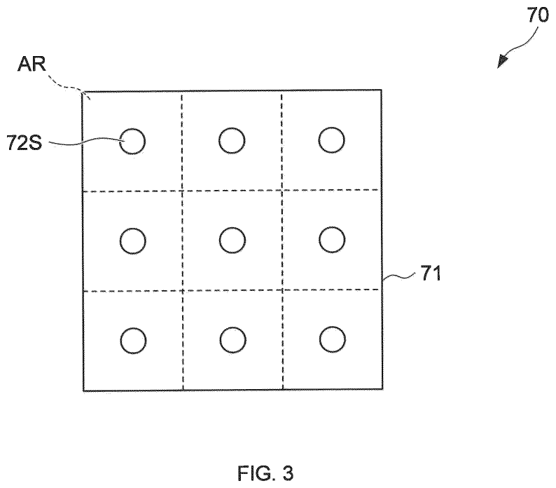

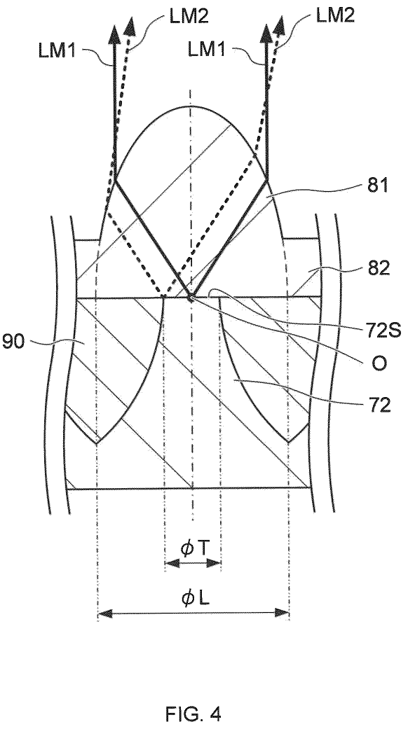

With reference to FIG. 1 and FIG. 2, a configuration of a light-emitting device 1 according to Example 1 will be described. FIG. 1 is a top view of the light-emitting device 1 according to Example 1. FIG. 2 is a cross-sectional view of the light-emitting device 1 illustrated in FIG. 1 taken along the line A-A. FIG. 3 is a top view of a light-collecting member 70 of the light-emitting device 1. FIG. 4 is an enlarged cross-sectional view of the light-collecting member 70 and an optical structure 80 of the light-emitting device 1, and is a drawing illustrating an emitted light from the optical structure 80.

### (Light-Emitting Device)

The light-emitting device 1 includes a substrate 10 having a cavity, a light-emitting element 20 disposed within the cavity of the substrate 10, a wavelength conversion member 50 disposed on an upper surface of the light-emitting element 20, the light-collecting member 70 disposed on the wavelength conversion member 50, and the optical structure 80 including a plurality of lens portions 81 disposed on the light-collecting member 70. The light-emitting device 1 includes a covering member 90 that fills inside of the cavity of the substrate 10, and covers from a side surface of the light-emitting element 20 through to a side surface of the wavelength conversion member 50 and up to at least a side surface of the light-collecting member 70.

### (Substrate)

The substrate 10 is an insulating substrate made of a ceramic, such as aluminum nitride (AlN), having an upper surface shape in rectangular. The substrate 10 is provided with a cavity formed of a wall portion extending upward along outer edges of a flat plate and an upper surface of the flat plate.

Note that the substrate 10 may be integrally molded so as to have a recessed portion opening upward, or may be formed to join a frame body having a frame shape along the flat plate and the outer edges of the flat plate. An insulating material, such as a resin material, other than the ceramic may be used for the substrate 10.

The substrate 10 includes a pair of substrate electrodes 12, 13 formed of a metal that can feed a power to the light-emitting element 20 from outside of the substrate 10 on a bottom surface of the cavity as illustrated in FIG. 2. For example, a wiring electrode is formed to electrically conduct to the outside of the substrate 10 via a through electrode or the like.

Note that, in the example, a step portion ST is provided at an upper end portion of an inner surface of the wall portion of the substrate 10. The step portion ST prevents the covering member 90 from climbing up to an upper surface of the optical structure 80.

The portion that extends above the step portion ST is a lens guard portion LG that protects a surface of the lens portions 81 of the optical structure 80.

### (Light-Emitting Element)

The light-emitting element 20 is a light-emitting diode (LED) having a rectangular parallelepiped shape and having a gallium-nitride (GaN)-based semiconductor structure layer that emits a blue-colored light. The light-emitting element 20 is disposed on the bottom surface of the cavity of the substrate 10 such that the side surface is separated away from an internal surface of the recessed portion of the substrate 10 as illustrated in FIG. 2.

The light-emitting element 20 includes a semiconductor structure layer (not illustrated) and a pair of element electrodes formed of an anode electrode 22 and a cathode electrode 23 on a lower surface of a translucent growth substrate 21, and the light-emitting element 20 is an LED element in flip chip connection configured to emit a light from the upper surface of the growth substrate. That is, the upper surface of the light-emitting element 20 is a light-emitting surface that emits a light.

The anode electrode 22 and the cathode electrode 23 of the light-emitting element 20 are electrically connected to the substrate electrodes 12, 13, respectively, formed on the cavity bottom surface of the substrate 10 via a joining member 30 of, for example, gold tin alloy (Au—Sn). That is, the light-emitting element 20 is mounted on the substrate 10 in a configuration of flip chip, and is energizable by being configured to be able to be powered from outside via the wiring electrode formed in the substrate 10.

### (Wavelength Conversion Member)

The wavelength conversion member 50 is disposed to cover the light-emitting surface of the light-emitting element 20 via a translucent adhesive material 40, such as a silicone resin.

In the example, a ceramic material made of alumina (Al₂O₃) containing yttrium aluminum garnet phosphor particles with cerium (Ce) as an activator agent (YAG:Ce) is used for the wavelength conversion member 50. The wavelength conversion member 50 converts a part of blue-colored light from the light-emitting element 20 entering from the bottom surface as a light incidence plane into a yellow-colored light, and emits a white-colored light from an upper surface.

Note that, for the wavelength conversion member 50, a glass material containing β-SiAlON phosphor particles with europium (Eu) as an activator agent (β-SiAlON:Eu) or a calcium fluoride (CaF₂) material containing potassium fluorosilicate (KSF, K₂SiF₆:Mn) phosphor particles with manganese (Mn) as an activator agent may be used.

B—SiAlON:Eu converts a blue-colored light into a green-colored light, and K₂SiF₆:Mn converts a blue-colored light into a red-colored light. The contained amounts of the respective phosphors are simply determined by conveniently setting the conversion percentage of the blue-colored light of the light-emitting element 20 corresponding to the application. It is allowed to overlap and dispose a plurality of the wavelength conversion members 50. Note that, when only the light emitted from the light-emitting element 20 is used, the wavelength conversion member 50 can be omitted. A dummy glass or the like is also allowed to be used.

In the example, the case where the wavelength of the emitted light of the light-emitting element 20 is converted using the wavelength conversion member 50 in a plate shape has been described. However, instead of the adhesive material 40, the wavelength conversion member 50, and an adhesive material 60 described below, a resin material containing the above-described phosphor particles may be used. In this case, the resin material containing the phosphor particles adheres the light-emitting surface of the light-emitting element 20 and a bottom surface of the light-collecting member 70.

### (Light-Collecting Member)

The light-collecting member 70 is a translucent member in which a base portion 71 having a flat bottom surface and a plurality of truncated pyramid portions 72 that extend upward from an upper surface of the base portion 71 are integrally formed. The light-collecting member 70 is a light inducing member that induces the light that has entered from the lower surface to light-emitting regions 72S.

In the example, a silicone resin is used for the light-collecting member 70.

The bottom surface of the base portion 71 is disposed to cover the upper surface of the wavelength conversion member 50 via the translucent adhesive material 60, such as a silicone resin. That is, the bottom surface of the base portion 71 is a light incidence plane of the light-collecting member 70.

The truncated pyramid portions 72 are arranged in sequence on the upper surface of the base portion 71. In the example, the truncated pyramid portions 72 are arranged in a sequence of three rows and three columns on the upper surface of the base portion 71.

The truncated pyramid portion 72 induces the light that has entered from the light incidence plane of the base portion 71 by the light-reflective covering member 90, described later, and emits the light from the light-emission region 72S that is an upper surface. That is, in the light-collecting member 70, each of the truncated pyramid portions 72 is a light inductor.

The truncated pyramid portion 72 has a side surface having an arc-shaped cross-sectional surface forming a recessed shape outward from an outer edge on a bottom surface to an outer edge of the light emission region 72S.

As illustrated in FIG. 3, in the example, the light emission region 72S has a circular upper surface shape. There are defined rectangular regions AR equally divided by grid-like equisector lines on the upper surface of the base portion 71, and the respective truncated pyramid portions 72 are formed on the rectangular regions AR. The respective truncated pyramid portions 72 are formed using the respective rectangular regions AR as bottom surfaces. That is, the truncated pyramid portions 72 use the respective rectangular regions AR in rectangular shapes as the bottom surfaces and the respective light emission regions 72S in circular shapes as the upper surfaces. Therefore, the upper surface of the base portion 71 of the light-collecting member 70 does not have a flat surface thereon.

In the top view, a center point of the bottom surface (the rectangular region AR) of the truncated pyramid portion 72 and a center point of the light emission region 72S are formed to correspond to one another.

### (Optical Structure)

The optical structure 80 has the plurality of lens portions 81 optically coupled immediately above the light emission regions 72S of the light-collecting member 70 and a supporting portion 82 supporting the plurality of lens portions 81 integrally formed as illustrated in FIG. 1 and FIG. 2. In the example, the silicone resin formed by, for example, injection molding is used for the optical structure 80. The optical structure 80 is, for example, adhered on the light emission regions 72S using a translucent adhesive material (not illustrated), such as a silicone resin.

As illustrated in FIG. 4, in the example, each of the plurality of lens portions 81 is a convex lens in an elliptical hemispherical shape with a long axis in the vertical direction in the drawing. The supporting portion 82 is formed to couple respective lower end portions of side surfaces of the plurality of lens portions 81. That is, the lens portion 81 has a midpoint O located on the bottom surface of the optical structure 80.

The midpoint O (the center point of the bottom surface of the lens portion 81) of the lens portion 81 and the center point of the light emission region 72S of the light-collecting member 70 are disposed at a position corresponding to one another. In other words, the respective centers of the plurality of light emission regions 72S corresponding to respective optical axes of the plurality of lens portions 81 of the optical structure 80 are disposed.

In view of this, as illustrated in FIG. 4, a light LM1 that has entered from the midpoint O of the lens portion 81 is emitted in an approximately perpendicular direction to the light-emitting device 1. A light LM2 that has entered from the lens portion 81 from an outer end of the light emission region 72S of the light-collecting member 70 is emitted slightly obliquely, but a light condensing action is obtained.

Note that a diameter φT of the light emission region 72S of the light-collecting member 70 is preferably formed to be (¼)φL<φT<(½)φL with respect to a diameter φL of the bottom surface of the lens portion 81.

Specifically, in order to reduce an oblique emission angle of the light LM2 that has entered the lens portion 81 from the outer end of the light emission region 72S of the light-collecting member 70, the diameter φT of the light emission region 72S is preferably less than ½ of the diameter φL of the bottom surface of the lens portion 81.

In order to reduce the light loss in the truncated pyramid portion 72, the diameter φT of the light emission region 72S preferably exceeds ¼ of the diameter φL of the bottom surface of the lens portion 81.

While in the example, there has been described the case where the respective adjacent lens portions 81 of the optical structure 80 do not overlap with one another, the adjacent lens portions 81 may be formed to partly overlap with one another. In this case, it is preferred that overlapping portions are provided within a range in which a light that has entered one lens portion 81 does not enter into another adjacent lens portion 81 via the overlapping portion or a light that has been emitted from one lens portion 81 does not enter again into another adjacent lens portion 81.

While in the example, there has been described the case where the lens portion 81 of the optical structure 80 is an elliptical hemisphere, the lens portion 81 may be in a parabolic hemispherical shape. The shape of the lens portion 81 is conveniently designable depending on a light distribution property, for example, a half-value angle of the emitted light of the light-emitting device 1.

Note that, in the example, a thermosetting resin, such as an epoxy resin, an acrylic resin, a polycarbonate resin, or a thermoplastic resin may be used as another material for the light-collecting member 70 and the optical structure 80. A thermoplastic amorphous fluororesin, a thermosoftening glass material, and the like are also allowed to be used. The thermosetting resin can be formed by, for example, injection molding using a metallic mold, and the thermoplastic resin and the glass material can be formed by, for example, press forming using a metallic mold. When the fluororesin is used, the surface of the light-collecting member 70 and the surface, excluding the upper surfaces of the lens portion 81 and the supporting portion 82 continuing to the lens portion 81, of the optical structure 80 undergo a plasma treatment to perform surface reforming such that the adhesive material 60 and the covering member 90 can be adhered.

The optical structure 80 is, for example, adhered on the light emission regions 72S using a translucent adhesive material (not illustrated). When the light-collecting member 70 and the optical structure 80 are formed of similar materials, it is preferred to use an adhesive material that uses a similar resin to those of the light-collecting member 70 and the optical structure 80 as a base material. When the light-collecting member 70 and the optical structure 80 are formed of dissimilar materials, it is preferred to use an adhesive material that uses a resin having an approximately equal (or close) refractive index to those of the light-collecting member 70 and the optical structure 80 as a base material.

When the light-collecting member 70 and the optical structure 80 are both a thermoplastic resin or a glass material, a direct bonding, such as friction fusion bonding, thermocompression bonding, or laser welding, is allowed.

In particular, by direct bonding, an optical interface between the light emission regions 72S and the optical structure 80 can be made disappeared, and thus, a light loss caused by the interface can be reduced.

### (Covering Member)

The covering member 90 is a light reflective covering member filling inside the cavity of the substrate 10. In the example, a translucent medium resin material, such as a silicone resin, containing light scattering particles, such as titanium oxide (TiO₂) particles, is used. For the light scattering particles, composite ceramic particles containing two or more of any of alumina, zirconia, and silica are allowed to be used. As for the composite ceramic particles, the particle itself has high reflection characteristics, and therefore it is not affected by a refractive index of the medium resin material, thereby being preferable as the light scattering particles.

The covering member 90 covers a region from an exposed surface and a side surface of the bottom surface of the light-emitting element 20 to the side surfaces of the truncated pyramid portions 72 of the light-collecting member 70. This causes the light emitted from the side surfaces of the light-emitting element 20, the wavelength conversion member 50, and the light-collecting member 70 to reflect inward.

### COMPARATIVE EXAMPLE

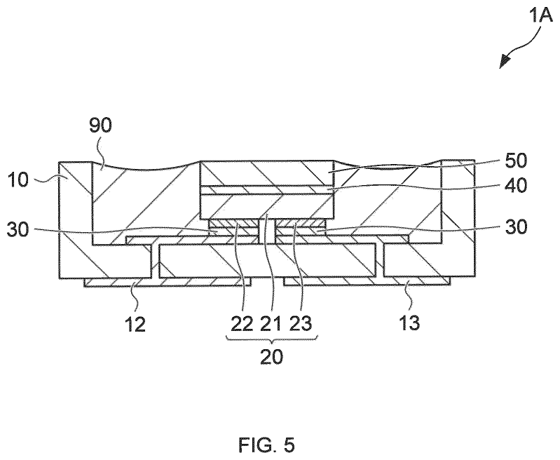

FIG. 5 is a drawing illustrating a cross-sectional surface of a light-emitting device 1A according to a comparative example of the present invention.

The light-emitting device 1A of the comparative example uses the same ones as those in the light-emitting device 1 of the example for the substrate 10, the light-emitting element 20, the wavelength conversion member 50, and the respective joining member 30 and adhesive material 40.

The light-emitting device 1A of the comparative example is the light-emitting device 1 of the example without the light-collecting member 70 or the optical structure 80. In the light-emitting device 1A of the comparative example, the substrate 10 has a wall portion whose height is approximately equal to the height of the upper surface of the wavelength conversion member 50.

### (Comparison of Light Distribution Properties Between Comparative Example and Present Example)

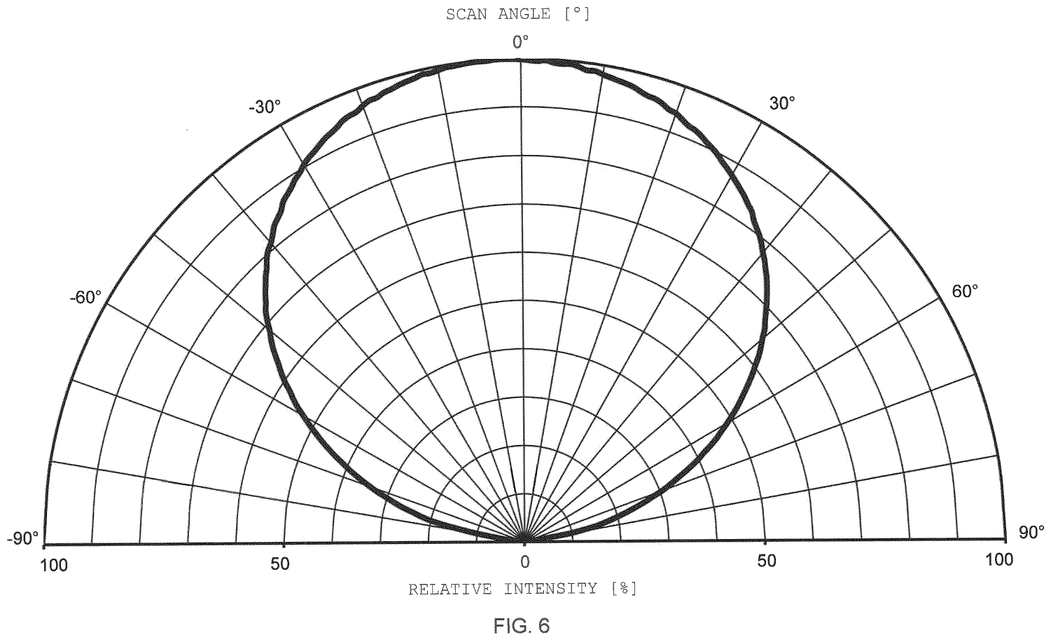

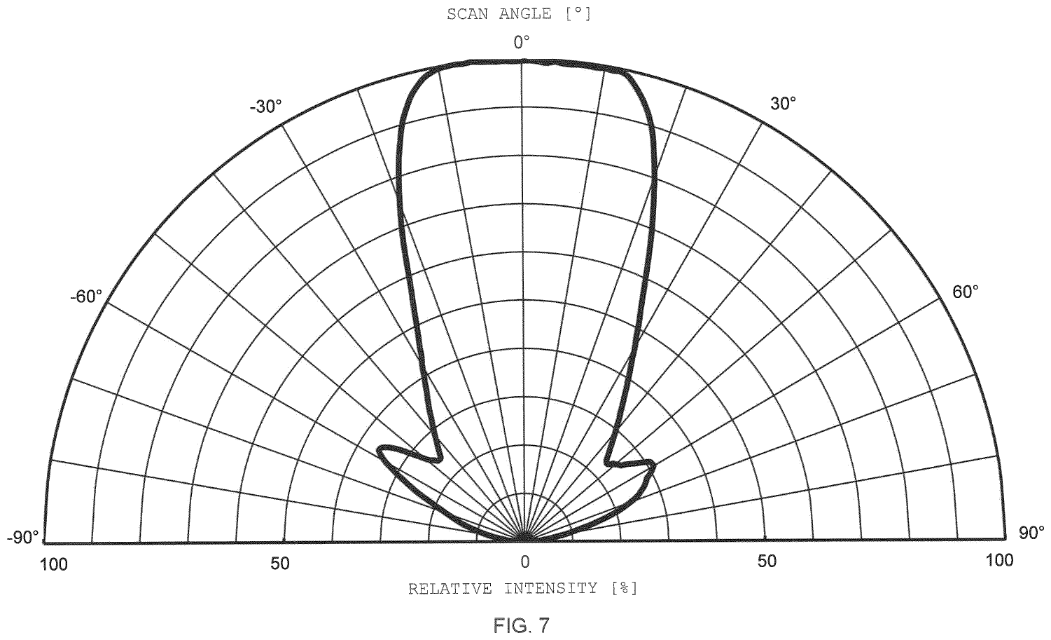

FIG. 6 illustrates a light distribution characteristic diagram of an emitted light of the light-emitting device 1A according to the comparative example. FIG. 7 illustrates a light distribution characteristic diagram of an emitted light of the light-emitting device 1 according to the example.

The perpendicular lines in FIG. 6 and FIG. 7 indicate optical axis directions of the light-emitting devices 1 and 1A. The fan-shaped ranges in FIG. 6 and FIG. 7 indicate light flux amount rates in the ranges of −90° to +90° with respect to the optical axis directions when the maximum light flux amount of a predetermined angle is 100%.

As illustrated in FIG. 6, the emitted light of the light-emitting device 1A according to the comparative example obtained a light distribution property approximately equal to a Lambertian light distribution. That is, the emitted light of the light-emitting device 1A according to the comparative example had an angle range at which 50% or more of the maximum light flux amount was obtained, that is, a half-value angle was approximately 120°.

As illustrated in FIG. 7, it can be seen that the emitted light of the light-emitting device 1 according to the example is emitted in an angle range narrower than that of the light-emitting device 1A according to the comparative example. Specifically, the emitted light of the light-emitting device 1 according to the example had a half-value angle of approximately 54°.

The light flux amount within the range of 54° to the optical axis of the emitted light of the light-emitting device 1 according to the example increased by approximately 10% with respect to the light flux amount within the range of 54° to the optical axis of the emitted light of the light-emitting device 1A according to the comparative example. In other words, the light-emitting device 1 according to the example while reducing the loss of the emitted light of the light-emitting element 20 within the range of 54° of the half-value angle, ensures narrowing the angle of the emitted light from the light-emitting device 1.

As described above, the light-emitting device 1 of the example includes the light-collecting member 70 that collects the light emitted from the upper surface of the wavelength conversion member 50 in the light emission regions 72S by the truncated pyramid portions 72, and emits the light to the outside of the light-emitting device 1 via the optical structure 80 including the elliptical-hemispherical-shaped lens portions 81 from the light emission regions 72S. This allows the light-emitting device 1 of the example to, while reducing the loss of the light emitted from the light-emitting element 20, achieve a narrow angled emitted light.

### (Modification 1)

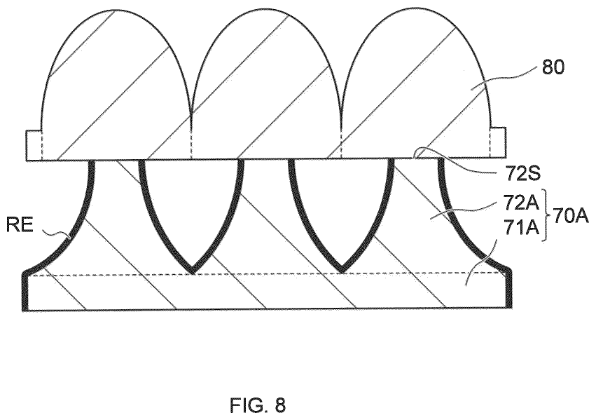

FIG. 8 is a cross-sectional view of a light-collecting member 70A as Modification 1 of the light-collecting member 70 of the light-emitting device 1 of the example.

Note that other configurations excluding the light-collecting member 70A are similar to those of the light-emitting device 1 of the example, and therefore, the descriptions are omitted.

In the light-emitting device 1 of the example, there has been described the case where the side surface of the light-collecting member 70 is covered by the covering member 90 made of a light-reflective resin material, and the light is induced to the light emission regions 72S.

The light-collecting member 70A of the modification has a dielectric multilayer film RE on its side surface formed by repeatedly laminating silicon oxide (SiO₂) and aluminum oxide (Al₂O₃).

The dielectric multilayer film RE can increase reflectivity of light compared with the covering member 90 containing light scattering particles. Therefore, when the light that has entered from the bottom surface of the light-collecting member 70A is induced to the light emission regions 72S, the light loss can be reduced. This allows the light flux amount of the light emitted from the lens portions 81 of the optical structure 80 to increase.

Note that the dielectric multilayer film RE can be formed by atomic layer deposition (ALD) after the bottom surface of the light-collecting member 70A and the light emission regions 72S are masked.

When the light-collecting member 70A with a side surface on which the dielectric multilayer film RE is formed is used, the covering member 90 is only necessary to fill up to at least an upper end of the side surface of the wavelength conversion member 50 from the cavity bottom surface of the substrate 10. Similarly to the light-emitting device 1 of the example, the covering member 90 may fill to cover the side surface of the light-collecting member 70A.

### (Modification 2)

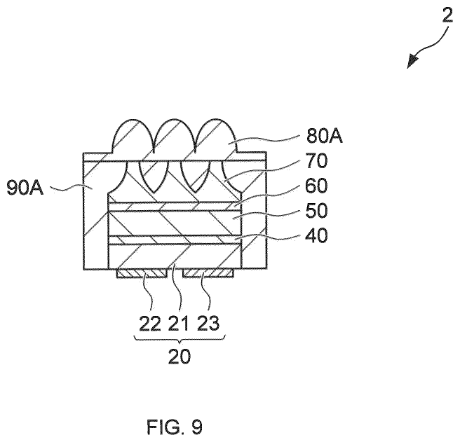

FIG. 9 is a cross-sectional view of a light-emitting device 2 as Modification 2 of the light-emitting device 1 of the example.

In the light-emitting device 2 of the modification 2, the anode electrode 22 and the cathode electrode 23 of the light-emitting element 20 are mounting electrodes electrically connected to the outside in a direct manner without using the substrate 10. That is, the light-emitting device 2 of the modification 2 is a light-emitting device of a chip size package type.

The light-emitting device 2 of the modification 2 is manufacturable by, for example, performing a dicing process twice.

Specifically, on the wafer on which the light-emitting element 20 formed continuously in a matrix, a plate-shaped member on which the wavelength conversion member 50 and the light-collecting member 70 are continuously formed in a matrix in a similar way is adhered via the adhesive materials 40 and 60 in the order, and thereafter, a first dicing blade performs a first dicing process.

Next, on the wafer to which the first dicing has been performed, a plate-shaped member on which an optical structure 80A is continuously formed in a matrix is adhered or joined on the light-collecting member 70.

Next, a covering member 90A is formed by, for example, transfer molding so as to fill a gap formed in the first dicing process and a gap between the truncated pyramid portions 72 of the light-collecting member 70.

Thereafter, a second dicing process is performed using a second dicing blade having a blade width smaller than that of the first dicing blade, and thus, the light-emitting device 2 of Modification 2 is manufacturable.

Note that the blade widths of the first dicing blade and the second dicing blade are selected to be a blade width that does not cause a light leakage from a side surface of the light-emitting device 2 after manufacturing.

### (Modification 3)

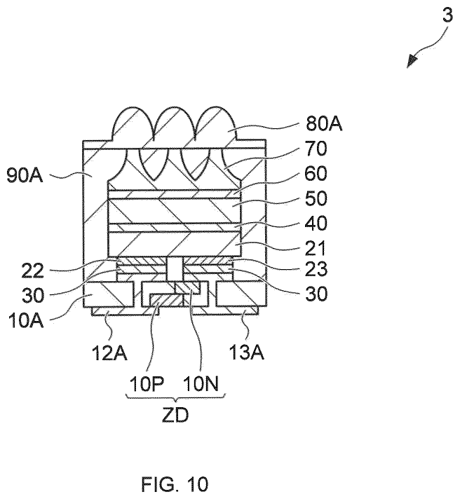

FIG. 10 is a cross-sectional view of a light-emitting device 3 as Modification 3 of the light-emitting device 1 of the example.

The light-emitting device 3 of Modification 3 is a light-emitting device of a chip size package type similarly to the light-emitting device 2 of Modification 2. The light-emitting device 3 of Modification 3 is different from Modification 2 in that the light-emitting element 20 is joined on a plate-shaped device substrate 10A.

The device substrate 10A is, for example, an insulating semiconductor substrate, such as a non-doped silicon. The device substrate 10A includes a pair of substrate electrodes 12A, 13A made of a metal that can feed a power to the light-emitting element 20 from the outside. The anode electrode 22 and the cathode electrode 23 of the light-emitting element 20 are electrically connected to the substrate electrodes 12A, 13A, respectively, formed on the device substrate 10A via the joining member 30 of, for example, gold tin alloy (Au—Sn).

On a side of a bottom surface inside the device substrate 10A, a p-type impurity diffused region 10P is formed to be in contact with the substrate electrode 12A. On a side of an upper surface inside the device substrate 10A, an n-type impurity diffused region 10N is formed to be in contact with the substrate electrode 13A. The p-type impurity diffused region 10P and the n-type impurity diffused region 10N are formed to be in contact with (join with) one another inside the device substrate 10A.

That is, the substrate electrode 12A and the substrate electrode 13A are electrically connected via a zener diode ZD connected in a reversed polarity to the light-emitting element 20 within the device substrate 10A.

Usually, it is preferred to provide a zener diode for reverse voltage application protection in the gallium-nitride-based light-emitting element that emits a blue-colored light.

As described above, forming the zener diode ZD inside the device substrate 10A eliminates the need for additionally disposing a zener diode outside the light-emitting device 3 in the light-emitting device 3 of a chip size package type. This ensures, for example, obtaining advantageous effects, such as improvement in implement density of the light-emitting device 3. Note that it is also possible to dispose a varistor, a capacitor, and the like, other than the zener diode. Furthermore, a transistor circuit that controls the emission of light of the light-emitting element 20 can be incorporated.

A method for manufacturing the light-emitting device 3 of Modification 3 is basically similar to that of the light-emitting device 2 of Modification 2.

Specifically, on a wafer on which the device substrate 10A is continuously formed in a matrix, the light-emitting element 20, the wavelength conversion member 50, and the light-collecting member 70 are mounted in the order using, for example, a die bonder.

Next, the plate-shaped member on which the optical structure 80A is continuously formed in a matrix is adhered or joined on the light-collecting member 70.

Next, the covering member 90A in a liquid form before hardening is injected from a hole provided in a part of the optical structure 80A so as to fill the gap between the upper surface of the device substrate 10A and the bottom surface of the plate-shaped member of the optical structure 80A, and thereafter, thermal hardening and the like forms the covering member 90A.

Thereafter, singulation by performing a dicing process allows manufacturing the light-emitting device 3 of Modification 3.

As described above, the described examples do not intend to limit the range of the invention. The described examples are allowed to be performed in various configurations as in Modifications 1 to 3, and are allowed to be variously omitted, replaced, and changed within a range not departing from the gist of the invention. For example, the structure in which a frame with a height of the lens portion 81 is provided at the peripheral edge portion of the optical structure 80 of the light-emitting device 1 of Example 1, and the covering member 90 fills up to the height of the frame is possible. The structure in which the covering member 90 covers up to a height of a base portion 71A of the light-collecting member 70A in Modification 1 is also possible. Thus, the described examples are included in the range of the invention and the gist, and are also included within the range of the invention described in the claims and the equivalent thereof.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed Examples but may be practiced within the full scope of the appended claims. The present application is based upon and claims the benefit of priority from the prior Japanese Patent Application No. 2023-083846 filed on May 22, 2023, the entire contents of which are incorporated herein by reference.

What is claimed is:

1. A light-emitting device comprising:
a light-emitting element having a rectangular parallelepiped shape, the light-emitting element having an element electrode surface on which a pair of element electrodes made of a cathode and an anode are formed on a lower surface and a light-emitting surface on an upper surface opposed to the element electrode surface;
a translucent light-collecting member disposed on the light-emitting surface of the light-emitting element, the light-collecting member having a plurality of light emission regions separated away from one another on a surface opposite of a surface opposed to the light-emitting surface; and
an optical structure formed to respectively overlap a plurality of the respective light emission regions viewed from above, the optical structure having a plurality of convex lens portions in convex in an upper side.

2. The light-emitting device according to claim 1, wherein
the light-collecting member is made of a light inductor having a base portion with an upper surface shape in a rectangular shape covering the light-emitting surface of the light-emitting element and a plurality of truncated pyramid portions each having a shape extending upward from an upper surface of the base portion and tapering upward, and
the plurality of truncated pyramid portions have respective upper surfaces that are the light emission regions.

3. The light-emitting device according to claim 2, wherein
rectangular regions made by equally dividing the region where the light inductor is formed on the upper surface of the base portion by grid-like equisector lines are respective bottom surfaces of the plurality of truncated pyramid portions.

4. The light-emitting device according to claim 1, wherein
the plurality of lens portions of the optical structure has a shape of an elliptical hemisphere or a parabolic hemisphere.

5. The light-emitting device according to claim 1, wherein
respective centers of the plurality of light emission regions corresponding to the plurality of respective lens portions are disposed on respective optical axes of the plurality of lens portions of the optical structure.

6. The light-emitting device according to claim 1, comprising
a wavelength conversion member between the light-emitting surface of the light-emitting element and a surface opposed to the light-emitting surface of the light-collecting member.

7. The light-emitting device according to claim 6, wherein
the wavelength conversion member is a ceramic plate or a resin layer containing a phosphor.

8. The light-emitting device according to claim 2, comprising
a light-reflective covering member that covers a side surface of the light-emitting element and respective side surfaces of the plurality of truncated pyramid portions.

9. The light-emitting device according to claim 1, comprising
an optical multilayer film that covers respective side surfaces of the plurality of truncated pyramid portions.

10. The light-emitting device according to claim 1, comprising
a device substrate made of a silicon, the device substrate having a pair of substrate electrodes that electrically coupling to the pair of respective element electrodes of the light-emitting element, wherein
the pair of substrate electrodes are electrically connected via a p-type impurity diffused region and an n-type impurity diffused region formed to have a reversed polarity to the light-emitting element inside the device substrate.
